(19) United States
(12) Patent Application Publication
(10) Pub. No.: US 2009/0289390 A1
(43) Pub. Date: Nov. 26, 2009

(54) Direct silicon or reactive metal casting

(75) Inventors: Franz Hugo, Aschaffenburg (DE); Ronald J. Reis, Moses Lake, WA (US)

Correspondence Address: KLARQUIST SPARKMAN, LLP, 121 SW SALMON STREET, SUITE 1600, PORTLAND, OR, 97204, US

(73) Assignee: REC Silicon, Inc.

(21) Appl. No.: 12/378,243

(22) Filed: Feb. 11, 2009

Related U.S. Application Data
(60) Provisional application No. 61/128,847, filed on May 23, 2008.

(51) Int. Cl. C23C 16/24; B28B 1/14

(52) U.S. Cl. 264/81; 425/3

(57) ABSTRACT

A method for producing solid multicrystalline silicon ingots or wafers, comprising:
introducing a silicon-bearing gas into a reactor chamber, wherein the reaction chamber includes a reactor chamber wall having (i) an inside surface facing a reaction space and (ii) an opposing outside surface, and a product outlet;
generating a plasma in the reactor space;
thermally decomposing the silicon-bearing gas by subjecting the silicon-bearing gas to a sufficient temperature to produce liquid silicon;
maintaining the inside surface of the reactor chamber wall at an equilibrium temperature below the melting point temperature of silicon while thermally decomposing the silicon-bearing gas; and
introducing the liquid silicon from the product outlet directly into a module for casting the liquid silicon into solid multicrystalline silicon ingots or multicrystalline silicon wafer.

This application claims the benefit of U.S. Provisional Application No. 61/128,847, filed May 23, 2008, which is incorporated herein by reference in its entirety.

### FIELD

The disclosure relates to methods, apparatus and systems for treating a silicon-bearing material or a reactive metal material, and to methods, apparatus and systems for casting silicon or reactive metal into ingots or wafers.

### BACKGROUND

Ultrapure or electronic grade silicon is a critical raw material for both the semiconductor (SC) and photovoltaic (PV) industries. While there are alternatives for specific PV applications, polysilicon will remain the preferred raw material in the near and foreseeable future. Hence, improving the availability of and economics for producing polysilicon will increase the growth opportunities for both industries.

The majority of polysilicon is produced by the commonly called Siemens hot-wire method with silane or trichlorosilane (TCS) as the silicon-bearing gas (SBG) source. The SBG, usually mixed in other inert or reaction gases, is pyrolytically decomposed and deposited onto a heated silicon filament. Another method is the pyrolytic decomposition of SBG in fluidized beds. This is an attractive alternative to produce polysilicon for the PV and semiconductor industries due to significantly lower energy consumption and the possibility for continuous production. These benefits stem from the excellent mass and heat transfer and increased surface for deposition. Compared with the Siemens-type reactor, the fluidized bed reactor offers considerably higher production rates at a fraction of the energy consumption. The fluidized bed reactor will also be more continuous and highly automated to significantly reduce labor costs as well.

Silane, or higher order silanes, used as the SBG in the Siemens or fluidized bed reactor process has a disadvantage over TCS in that it can undergo a (homogeneous) gas phase decomposition to powder particles in addition to the (heterogeneous) polysilicon deposition. The temperature at which the decomposition occurs is called the critical nucleation temperature (CNT). The CNT depends on the SBG species, SBG partial pressure, total pressure and type of inert dilution gas. Once the CNT is reached, the particle concentration will increase 10⁴-10⁶ times over a 1-5° C. range. Nucleus silicon powder particles are typically 1-100 nm in size depending on the residence time and can be amorphous or crystalline. In either case, there exists a moderate concentration of non-bonded electrons on the surface of these particles, which enables the particles to readily agglomerate into larger powder particles. Depending on conditions, this powder can be anything from non-single nuclei particles, micron-sized round agglomerates to large particles extended to several 100 microns.

These powder particles (also known as silicon fines) are considered contaminants in the Siemens process if the polysilicon is subsequently used for the growth of a dislocation-free single crystal, particularly in the semiconductor industry. Therefore, in a Siemens process with silane or higher order silanes as the SBG, the reactor walls are kept cool, applying thermophoresis to drive the powder particles from the region near the hot rods where they are produced towards the cool reactor walls where they deposit. Removing the powder from the gas phase reduces the potential for contamination of the silicon rod.

In a fluidized bed reactor process, powder may adhere to granules and incorporate in the particle, thus contributing to the overall granular growth. However, a large portion of the powder will be entrained out of the fluid bed reactor with the outgoing gases. In a fluidized bed reactor process for granular silicon production, such fine silicon powder is considered a production loss since it does not contribute to granular material.

Silicon powder may also be produced in other SBG deposition processes, e.g., intentionally in a Free Space Reactor or unintentionally in Chemical Vapor Deposition (CVD) reactor for thin film deposition on a substrate. Another source of silicon powder is silicon ingot grinding or cutting. The production rates and silicon qualities vary considerably depending on the processes.

Powder produced as described in the processes above currently is recovered with great difficulty because it is a fluffy, low density, high surface area product, easily contaminated by airborne substances. In addition, the silicon powder is typically disposed of as a waste product or is offered at very low value into the merchant silicon market.

Multicrystalline PV cells or SC wafers are produced from ultrapure or high-grade polycrystalline silicon (polysilicon) in several production steps. SiO₂ or quartz is mined and reduced in large furnaces to metallurgical grade silicon with a purity of 97 to 99%. The metallurgical grade silicon is transformed into a silicon-bearing gas that is then further purified by distillation. The silicon-bearing gas is decomposed to produce polysilicon via the Siemens or fluidized bed reactor process. The material produced by the Siemens or fluidized bed reactor process is then re-melted and crystallized in the Czochralski process (for producing monocrystalline) or the Bridgman-Stockbarger process (for producing multicrystalline) to produce crystalline silicon ingots. The ingots then are cut into bricks having the desired wafer size. The silicon wafer is subsequently cut from the brick. This process is schematically represented in FIG. 8A.

### SUMMARY

Disclosed herein are methods for thermally treating a silicon-bearing material or a reactive metal in order to convert this material into a more useful product form. For example, the disclosed methods upgrade silicon powder from a low-grade, loose-packed, high surface area product to a silicon precursor shape suitable for processing into a solar cell. Avoiding contamination during the thermal treatment process is important for obtaining pure, particularly ultrapure, product. One contamination source is the materials that constitute the structural elements of the reactor system. According to the apparatus, systems and methods disclosed herein a skull layer comprising solid silicon or solid reactive metal is formed on at least a portion of the inside surface of the reactor. The solid skull layer prevents contact of the feed material and product with the surface of the reactor system, thus avoiding or minimizing contamination. The skull layer also provides a diffusion barrier that may prevent reactor wall elements from migrating into the resulting silicon product.

According to one embodiment, a method for producing silicon or a reactive metal is disclosed herein that comprises:

introducing a silicon-bearing feed or reactive metal feed into a reactor chamber, wherein the reactor chamber includes a reactor chamber wall having (i) an inside surface facing a reaction space and (ii) an opposing outside surface;

generating a first thermal energy within the reaction space sufficient to generate a liquid silicon product or a liquid reactive metal product;

generating a second thermal energy exterior to the reactor chamber wall such that a heat flow from the second thermal energy initially impacts the outside surface of the reactor chamber wall; and

establishing an inside surface wall temperature within a temperature range that is above or below a melting point temperature of the silicon or the reactive metal by controlling the first thermal energy source and the second thermal energy source.

In a further embodiment, a method for producing silicon is disclosed that comprises:

introducing silicon powder into a reactor chamber, wherein the reactor chamber includes a reactor chamber wall having (i) an inside surface facing a reaction space and (ii) an opposing outside surface;

generating a plasma in the reactor space;

thermally melting the silicon powder by subjecting the silicon powder to a temperature greater than the melting point of the silicon powder via the plasma, wherein the melting process produces liquid silicon;

maintaining the inside surface of the reactor chamber wall at an equilibrium temperature below the melting point of the silicon powder while thermally melting the silicon powder; and

solidifying the liquid silicon after it exits the reactor chamber.

An additional disclosed embodiment concerns a method for producing solid multicrystalline silicon that comprises:

introducing a silicon-bearing gas into a reactor chamber, wherein the reaction chamber includes a reactor chamber wall having (i) an inside surface facing a reaction space and (ii) an opposing outside surface, and a product outlet;

generating a plasma in the reactor space;

thermally decomposing the silicon-bearing gas by subjecting the silicon-bearing gas to a sufficient temperature to produce liquid silicon;

maintaining the inside surface of the reactor chamber wall at an equilibrium temperature below the melting point temperature of silicon while thermally decomposing the silicon-bearing gas; and

introducing the liquid silicon from the product outlet directly into a module for casting the liquid silicon into solid multicrystalline silicon ingot or wafer.

Also disclosed herein is a reactor system that comprises:

a silicon-bearing feedstock or a reactive metal feedstock;

a reaction chamber that includes a reactor chamber wall that defines a chamber reaction space and includes (i) an inside surface facing the reaction space and (ii) an opposing outside surface;

a plasma energy source coupled to the reaction chamber and configured to generate thermal energy within the chamber reaction space;

an exterior thermal energy source configured to subject the outside surface of the reactor chamber wall to heating, and located outside of the reactor chamber; and

a product outlet configured for withdrawing liquid silicon or liquid reactive metal from the reaction chamber.

The foregoing will become more apparent from the following detailed description, which proceeds with reference to the accompanying figures.

### BRIEF DESCRIPTION OF THE DRAWINGS

FIGS. 1A and 1B are schematics of one embodiment of the disclosed reactor system. FIG. 1A is an exploded view of a wall section of the reactor shown in FIG. 1B.

FIG. 2 is a schematic of a further embodiment of the disclosed reactor system.

FIG. 3 is a schematic of a reactor system that includes one solidification embodiment.

FIG. 4 is a schematic of a reactor system that includes another solidification embodiment.

FIG. 5 is a schematic of a reactor system that includes a further solidification embodiment.

FIG. 6 is a schematic of a temperature gradient in the disclosed reactor system.

FIG. 7 is a schematic of two heat flows in the disclosed reactor system.

In the figures like reference numerals refer to like elements unless otherwise specified.

FIG. 8A is a schematic representation of the prior art steps for producing a silicon wafer.

FIG. 8B is a schematic representation of one embodiment of the presently disclosed methods.

### DETAILED DESCRIPTION

The singular terms “a,” “an,” and “the” include plural referents unless context clearly indicates otherwise. The word “comprises” indicates “includes.” Unless otherwise indicated, description of components in chemical nomenclature refers to the components at the time of addition to any combination specified in the description, but does not necessarily preclude chemical interactions among the components of a mixture once mixed. Any numerical values recited herein include all values from the lower value to the upper value in increments of one unit provided that there is a separation of at least 2 units between any lower value and any higher value. As an example, if it is stated that the amount of a component or a value of a process variable is from 1 to 90, preferably from 20 to 80, more preferably from 30 to 70, it is intended that values such as 15 to 85, 22 to 68, 43 to 51, 30 to 32 etc., are expressly enumerated in this specification. For values, which have less than one unit difference, one unit is considered to be 0.1, 0.01, 0.001, or 0.0001 as appropriate. Thus all possible combinations of numerical values between the lowest value and the highest value enumerated herein are said to be expressly stated in this application.

As used herein, “multicrystalline” silicon denotes a different microstructure compared to the microstructure of “polycrystalline” silicon (polycrystalline silicon is also referred to as “polysilicon”). Polycrystalline silicon microstructure is the product resulting from the above-described Siemens process or fluidized bed reactor process. Polycrystalline silicon is the feedstock to produce multicrystalline silicon ingots in the conventional Bridgman-Stockbarger process or monocrystalline silicon ingots in the conventional Czochralski process. The multicrystalline silicon structure results from directional solidification of the liquid silicon. In general, the microstructure of polycrystalline silicon consists of individual small crystallites and usually results from silicon layer growth out of a vapor phase. Multicrystalline silicon consists of larger crystals that are aligned in one direction and are achieved when a molten amount of silicon is solified under a one dimensional temperature gradient.

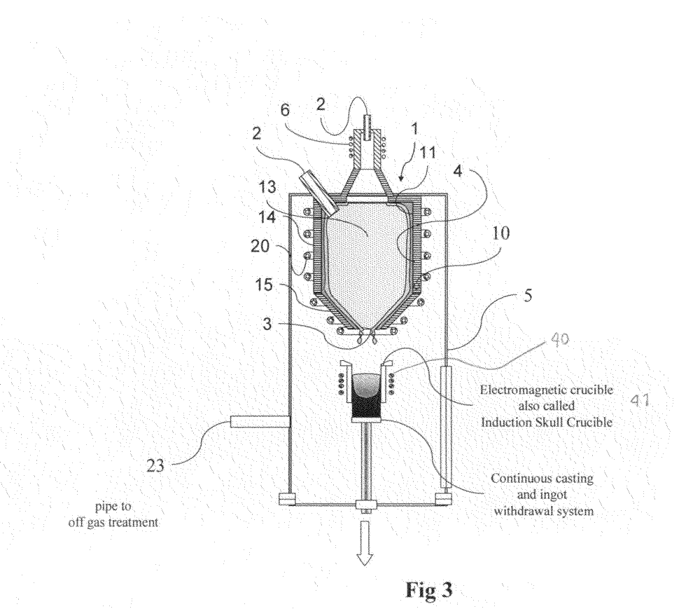

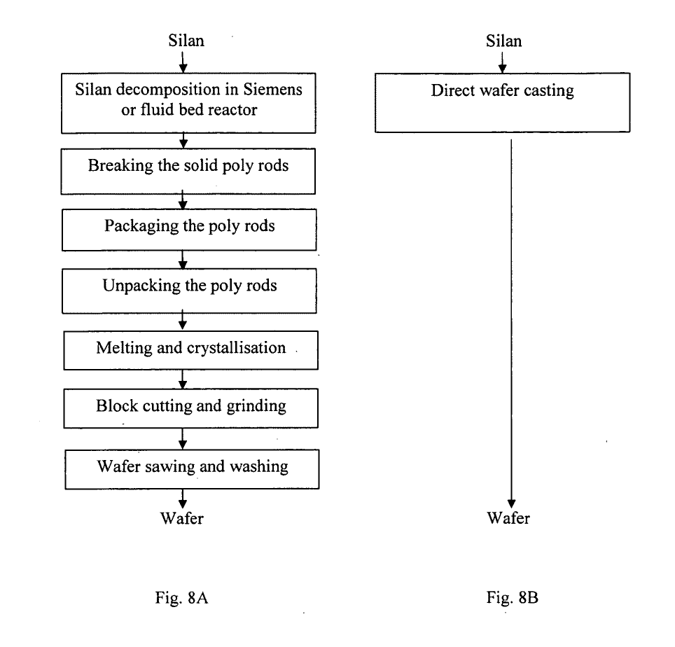

According to the presently disclosed direct casting methods, liquid silicon may be transformed directly into a silicon film of the same thickness as a finished silicon wafer. The methods feed an ultrapure or high-grade stream (e.g., electronic grade or solar grade) of liquid silicon directly into a casting unit in which the silicon is solidified. In the presently disclosed methods a silicon-bearing gas is transformed into a solid silicon wafer or ingot (via liquid silicon) in a unitary process that is integrated within a single manufacturing unit or module. For example, the complete process may be performed within a single hermetically sealed containment chamber (see FIG. 3). FIG. 8B depicts a schematic representation of how the presently disclosed methods avoid several steps of the prior art method. The disclosed methods avoid re-melting of the silicon (re-melting inevitably causes contamination) meaning that 8 to 25 kW/kg of silicon may be conserved. The disclosed methods for direct casting of wafers avoid material losses caused by the sawing of the wafer, and reduce the energy required to produce a wafer. For example, in conventional wafer cutting processes up to about 60% of the multicrystalline silicon ingot is lost as scrap-material.

The reactor systems disclosed herein are thermally designed to maintain a substantially solid skull layer of silicon or the reactive metal feed on an inside surface of a reactor chamber wall. Moreover, the thermal design of the system enables more precise controlling of the skull layer thickness. The skull layer may cover only a portion of the inside wall surface or it may cover the entire surface area of the inside surface. Formation of the solid skull layer on the inside surface of the reactor chamber wall protects the chamber wall construction material from corrosive attack by the liquid silicon or the liquid reactive metal. In other words, the skull layer prevents direct contact between the chamber wall and the liquid silicon thus minimizing contamination of the liquid silicon product. The skull layer is formed by maintaining the inside surface of the reactor chamber wall at a temperature below the melting point of the silicon or the respective reactive metal melting point.

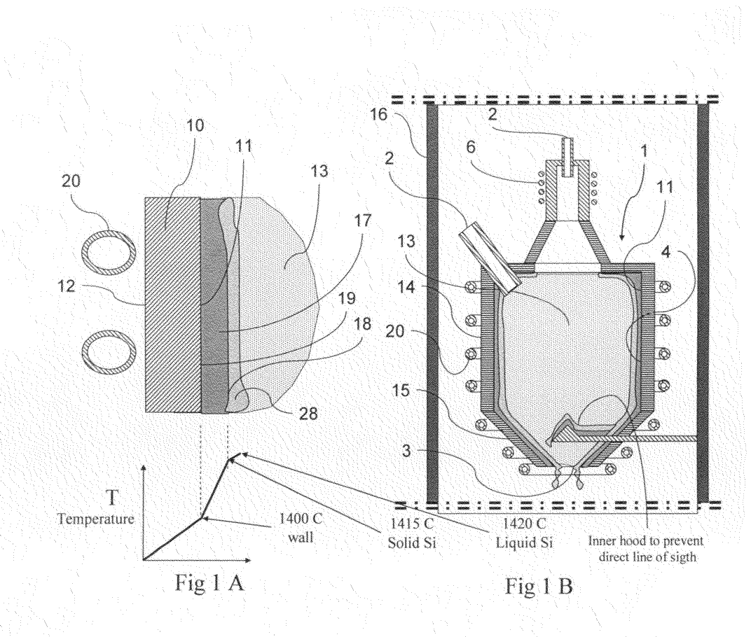

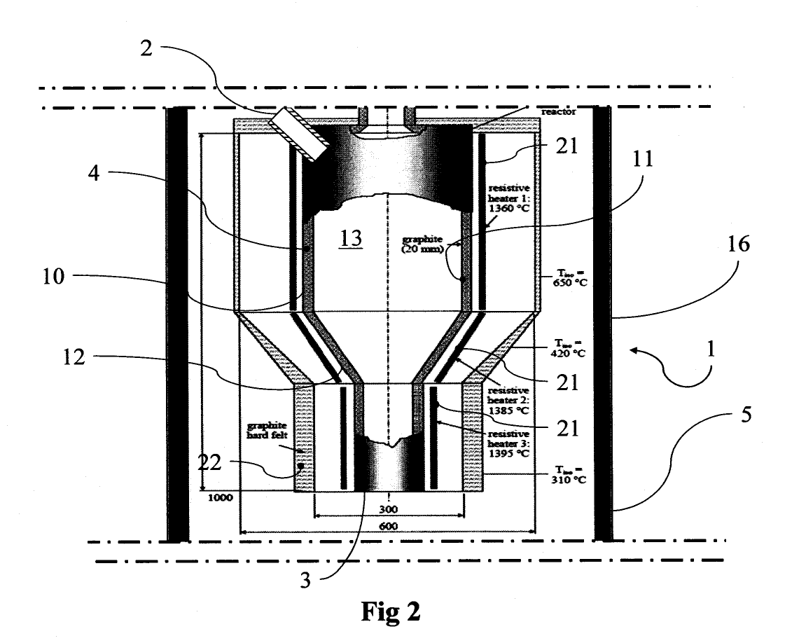

The thermal control system includes a combination of an inner thermal energy source inside the reactor chamber and an exterior thermal energy source located outside or external to the reactor chamber. The exterior thermal energy source is also located within a confinement chamber that also encompasses the reactor chamber. The exterior thermal energy source may provide heat directly to the outside surface of the reactor wall via induction heating, resistance heating, or a combination of both. In an embodiment shown in FIGS. 1A, 1B, 3, and 7B the exterior energy source is an induction coil(s). In another embodiment shown in FIG. 2, the exterior energy source is a resistance heater(s). Microwave is another possible exterior energy source. The inner thermal energy source may be a plasma as described in more detail below. Alternatively, the inner thermal energy source may be electron beams, resistance heating elements or induction heating elements.

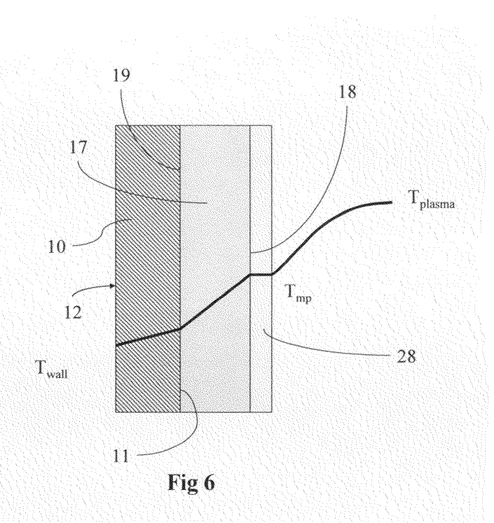

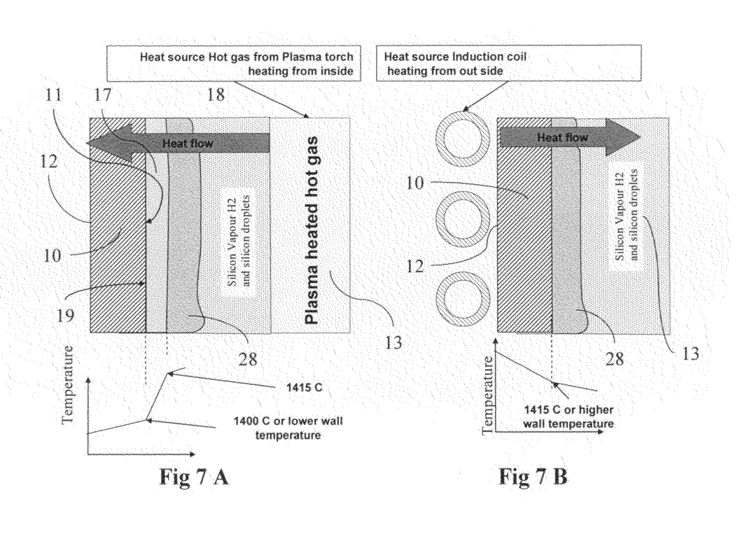

The heat flows generated by the inner thermal energy source and the exterior energy source are shown in FIG. 7A and 7B, respectively. The inner heat flow progresses as follows: a heated reaction gas→liquid silicon film→solid silicon skull layer→reactor chamber wall. The exterior heat flow progresses as follows: reactor chamber wall→solid silicon skull layer→liquid silicon film. The inner thermal energy source provides the energy for the thermal decomposition of the feedstock material. The exterior thermal energy source provides for precise control of the reactor chamber wall inside surface temperature in a range sufficiently close to (but under) the melting point of the silicon or the reactive metal. The resulting temperature gradient is shown in FIG. 6.

The exterior thermal energy source may be configured into at least one temperature control zone. The different temperature control zones may be used to establish a different temperature profile or zone along the axial length of the reactor chamber.

As described above, the processes disclosed herein establish a temperature gradient from the outside surface of the reactor chamber to the reaction space inside the reactor chamber as shown in FIG. 6. The specific temperature gradient will vary depending upon several factors including the feedstock material, the feed rate, operating pressure within the reactor space, etc. In addition, the temperature gradient is time dependent since it will change beginning from start-up of the reactor to steady-state operation. Accordingly, the specific temperatures of the thermal control system will vary. However, in general, the inside surface of the reactor chamber wall may be 1 to 300° C. below the melting point of the feedstock material, more particularly 1 to 100° C. below the melting point of the feedstock material; the skull layer may be at the melting point of the feedstock material to 300° C. below the melting point of the feedstock material, more particularly the melting point to 100° C. below the melting point; and the reactor space may be at the melting point of silicon or the reactive metal up to more than 5000° C.

The overall thermal control approach may also include thermal insulation as described below in more detail.

Illustrative embodiments of the reactor system are shown in FIGS. 1-5. In general, a reactor system 1 includes at least one feedstock inlet 2, at least one liquid product outlet 3, a reactor chamber 4, an outer containment chamber 5, and a plasma generating source 6.

The feedstock inlet 2 may be any type of port or valve that enables controlled introduction of the feedstock into the reactor chamber 4. For example, the inlet 2 may be a nozzle such as a water cooled structure made from quartz, graphite and/or silicon.

The reactor chamber 4 includes a reactor chamber wall 10 that defines a reaction space 13 located within the reactor chamber wall 10. The reactor chamber wall 10 includes an inside surface 11 facing the reactor space 13 and an opposing outside surface 12. The reactor chamber may be provided in any shape such as cylindrical, oval, rectangular, etc. Cylindrical reactor chambers are shown in the Figures. In certain embodiments, the reactor chamber may have several different sized and/or shaped sections. For example, FIG. 1 depicts a first cylindrical section 14 and a second tapered or conical section 15. The second section 15 tapers into the product outlet 3. The reactor chamber wall 10 may be made from made from any material that resists corrosion and contamination of the feedstock or product, is amenable to skull layer formation, and offers the desired heat or energy conductive or resistant properties. Illustrative wall construction materials include graphite, molybdenum, tungsten, titanium, a ceramic (e.g., alumina), and quartz.

The inside surface 11 area should be sufficiently large to enable collection and liquid conversion of the feedstock material on the inside surface 11. Depending on the desired throughput in kg/h, the inside surface 11 area should be in a range of 0.2 m² to 5 m² for a product throughput in a range of 1 to 50 kg/h.

The power supply for generating the plasma may be any type of power supply. Illustrative plasmas include RF, DC arc, or microwave plasma. Depending upon the specific plasma type, the plasma power may range from 1 to 1000 kW, more particularly 10 to 200 kW.

The product outlet 3 may be coupled to a product collection module and/or product solidification module. For example, the product can be cooled during free fall through a solidification tower and then collected in bins if mm-sized droplets are desired. Droplets with a diameter of 0.5 mm will solidify and cool down to a temperature of about 600° C. after falling through a distance of approximately 6 to 8 meters. At this temperature the solidified silicon droplets can be collected in product collector bins that may be water cooled. Alternatively it is also possible to increase the free falling height to further cool the droplets and collect the silicon product in bins without water cooling. It is also possible to line the collection bin and the free fall tower with silicon tiles or other non-contaminating coating/liner material.

In the embodiment of FIGS. 1A and 1B, at least one heat induction coil(s) 20 is located at or near the outside surface 12 of the reactor chamber wall. The coil 20 may surround the entire periphery or only a portion of the periphery of the reactor chamber. The coil 20 is made from any heat transfer material that enables sufficient heating of the reactor chamber wall. The coil 20 also can act as a heat sink and supplement the outer water-cooled containment chamber wall that also acts as a heat sink.

In the embodiment of FIG. 2, at least one resistance heater(s) 21 is disposed at or near the outside surface 12 of the reactor chamber wall. The resistance heater 21 heats the reactor chamber wall. The FIG. 2 embodiment also includes an insulation element 22 disposed between the reaction chamber wall and the containment chamber wall. The insulation thickness may be designed with different thicknesses along the vertical height axis of the reactor.

In another embodiment (not shown), no exterior thermal energy source for the reactor chamber is present. In other words, only a thermal energy source for generating thermal energy within the reaction space is present.

The outer containment chamber 5 is shown, for example, in FIGS. 2 and 3. The containment chamber 5 hermetically seals at least the reaction chamber 4. The containment chamber 5 includes a containment chamber wall 16 that may be water-cooled. The water-cooled containment chamber wall 16 also can be a heat sink for the reactor chamber thermal energies and heat flows described above.

FIGS. 3-5 illustrate several different solidification modules that can be coupled to the reactor system.

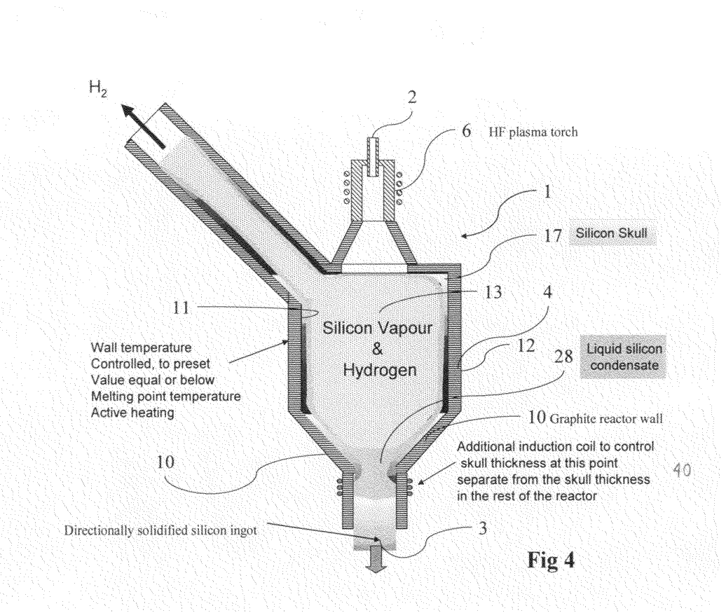

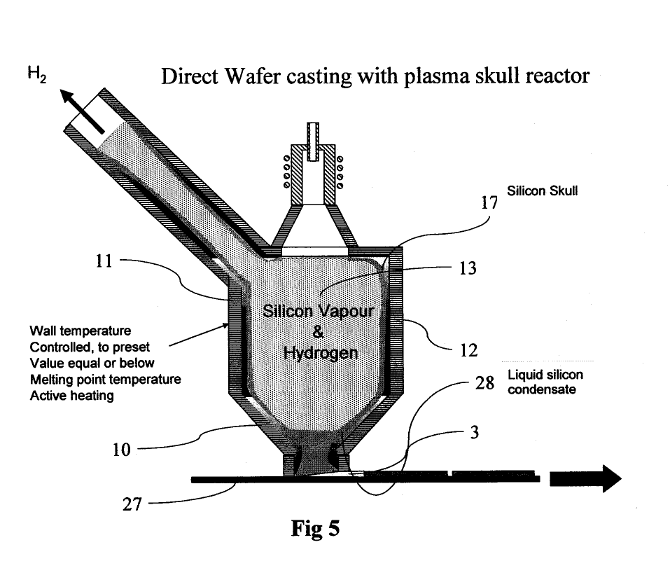

FIG. 3 includes an electromagnetic crucible coupled to a continuous casting system that enables the casting of silicon ingots. FIG. 4 depicts a configuration that enables production of directionally solidified silicon ingot. The liquid silicon from the outlet 3 can be channeled into the electromagnetic crucible. The advantages of direct coupled electromagnetic casting include no additional cost for transport containers, silicon is not re-melted, and contamination is minimized since ultrapure silicon is solidified in a non-contaminating skull layer crucible. FIG. 5 depicts a configuration that enables direct wafer casting by introducing the liquid silicon product of the presently disclosed reactor system onto a moving horizontal support substrate 27. Illustrative materials for support substrate 27 include graphite, silicon carbide, silicon nitride, aluminum oxide, zirconium oxide or mullite. U.S. Pat. No. 4,670,096, incorporated herein by reference, describes a process for direct wafer casting with liquid silicon onto a moving horizontal support.

In more detail, FIGS. 3 and 4 depict at least one induction coil 40 for heating an upper portion of an electromagnetic casting crucible 41, which may be water cooled. The induction coil 40 may be used to melt the skull layer to a thickness below 1 mm to break the skull layer during ingot withdrawal. The liquid silicon then will form a new skull layer. Skull layer formation and breakage cycles in the crucible can be repeated as necessary. The ingot can be withdrawn in incremental steps. An example of an electromagnetic casting crucible is described in EP1154047. FIG. 3 also includes an off gas port 23 that connects to an off gas treatment system.

In more detail, FIG. 5 depicts a design wherein the liquid product outlet 3 has been configured to be in the form of a molding element. The cross-section interior dimensions and shape of the orifice at the exit of the liquid product outlet are such that a product stream of liquid silicon exits in the desired shape and dimension for flowing onto the horizontal support substrate 27. For example, the exit surface of the liquid product outlet may be angled or tapered relative to the plane of the horizontal support substrate 27. The liquid product outlet structure may be configured to permit free vertical movement, as well as a tilting movement of the outlet structure. An after-heater may be located downstream of the liquid product outlet 3 to allow completion of the directional solidification and to obtain a smooth wafer surface.

When the liquid silicon makes contact with the material of the support substrate 27, a thin layer of solidified multicrystalline silicon (e.g., a silicon foil) will form, provided the temperature of the substrate 27 is below the melting point of silicon. The solidified layer will continue to grow by removal of heat from the undersurface of the support during the forward movement under the product outlet 3 and the after-heater so long as contact with the liquid phase is maintained. At the state of dynamic equilibrium, a growth wedge corresponding in length to the effective length of product outlet 3 will be formed.

According to another embodiment for direct casting of ingots, the liquid silicon may be introduced directly into a continuous casting crucible module similar to that shown in U.S. Pat. No. 4,936,375, which is incorporated herein by reference in its entirety. In this embodiment a bed is located beneath the liquid product outlet 3. The bed defines a cavity for receiving the liquid silicon from the outlet 3. A pool of liquid silicon forms in the bed cavity. A flow channel is formed by an opening in the bed wall, permitting a stream of the liquid silicon to flow from the pool into a mold in which the silicon is solidified into an ingot as a result of cooling fluid circulated through pipes in the mold. The ingot is withdrawn downwardly from the mold and, in order to provide a uniform crystal structure, the ingot should be withdrawn continuously at a substantially uniform rate corresponding to the rate of introduction of liquid silicon into the mold through the flow channel. In an alternative embodiment, the liquid silicon from the liquid product outlet 3 may be introduced directly into the mold from above without first entering a bed cavity.

According to another embodiment for direct casting of wafers or silicon strips, the liquid silicon may be introduced directly into a module similar to that shown in U.S. Pat. No. 4,212,343, which is incorporated herein by reference in its entirety. In this embodiment a continuous thin silicon strip may be formed be formed by forcing the liquid silicon onto the surface of a moving chill body under pressure through a slotted nozzle located in close proximity to the surface of the chill body. A further alternative module for forming a silicon ribbon on a moving chill surface is shown in U.S. Pat. No. 4,274,473, which is incorporated herein by reference in its entirety.

Operation of the reactor system may be initiated by heating the reactor chamber wall (via thermal energy from the exterior heat source, the inner heat source, or a combination of both the exterior and the inner heat sources) to greater than the melting point of the feedstock material. This pre-heating with a silicon-bearing material present will form a silicon carbide layer on the graphite reactor chamber wall. The reactor chamber wall temperature then would be lowered so that the inside surface would be below the melting point of the feedstock material. The material melting in the reaction space 13 will contact the inside surface thus initiating formation of the solid (frozen) skull layer 17. The skull layer 17 includes an inner surface 18 and an opposing wall contact surface 19. A temperature gradient is established across the reactor chamber wall, the skull layer and the gas in the reaction space as shown in FIG. 6. At thermal equilibrium conditions the skull layer thickness is no longer increasing, and the skull layer temperature reaches liquid material temperature on the surface 18 facing the reaction space 13 of the reactor. A liquid silicon film 28 will condense at the inner surface 18, and then flow along the inner surface 18 down the vertical axis of the reactor chamber. The melting process may also produce silicon vapor.

In the case of a silicon-bearing material feedstock, the maximum chamber wall inside surface 11 temperature should not exceed 1414° C. (1° C. less than the melting point of silicon) during skull layer formation and steady state operation. In certain embodiments the inside surface 11 temperature may range from 1115 to 1414° C., more particularly 1215 to 1414° C. The heat from the exterior thermal energy source maintains the reactor chamber wall temperatures at the desired temperature ranges allowing controlling of the skull thickness through controlling the wall temperature.

The heat flow from the reactor chamber typically is dissipated to a heat sink external to the reactor chamber. The heat sink may be active cooling (e.g., water cooled-containment chamber walls) and/or passive cooling such as insulation.

The feedstock material is introduced into the reactor chamber 4 via the inlet 2. The feedstock material may be any silicon-bearing material or a reactive metal. The silicon-bearing material may be solid silicon such as silicon powder or fines (as described in more detail herein), or a silicon-bearing gas such as silane, disilane, higher order silanes (SiₙH₂ₙ₊₂), dichlorosilane, trichlorosilane, silicon tetrachloride, dibromosilane, tribromosilane, silicon tetrabromide, diiodosilane, triiodosilane, silicon tetraiodide or a mixture thereof. Reactive metals such as titanium or zirconium could also be reduced using the process and apparatus disclosed herein. The silicon powder introduced into the reactor system may be small silicon particles (fines/powder) produced from silicon handling (e.g., breaking, grinding or cutting) or by any process that decomposes a silicon-containing gas. The powder may be dispersed or suspended in a carrier medium for injecting into the reactor system. For example, the carrier medium may be a gas that is inert to silicon and/or that has a relatively low ionization potential such as Ar.

The operating pressure in the reaction space 13 may range from 0.1 bar to 2.0 bar, more particularly 0.5 bar to 2.0 bar.

If the feedstock material is a silicon-bearing gas, the critical temperature is the thermal decomposition temperature at which the gas decomposes into a liquid. Thus, the inside surface of the reactor chamber wall is maintained at an equilibrium temperature below the melting point temperature. The embodiments shown in FIGS. 4 and 5 enable the production of a silicon ingot (FIG. 4) or a wafer (FIG. 5) directly from a silicon-bearing gas (e.g., silane) feedstock thus avoiding the costly step of forming, re-melting and cutting of polycrystalline silicon. A second gas, hydrogen, is present with the silicon-bearing gas in the reaction space 13. The hydrogen results from the thermal decomposition of the SiH₄ to Si and hydrogen.

The skull layer should have a thickness that is sufficient to protect against contamination of the liquid product by the reactor chamber wall material. However, the skull layer thickness should not so great that it occupies an unnecessary amount of the space inside the reactor chamber, thus detrimentally diminishing the available reaction space. An unnecessarily thick skull layer will also be more difficult to be thermally controlled at the equilibrium thickness. In general, the average skull layer thickness should be 0.01 to 200 mm, more particularly 0.1 to 30 mm.

Liquid silicon or liquid reactive metal flows through the liquid product outlet 3. The geometrical form (and size) of the liquid product can be controlled by the design of the product outlet 3. For example, the outlet 3 can be designed to discharge (e.g., jetting through a nozzle) droplets or spheres (which are the preferred physical form of feedstock for mono- or multi-crystalline ingot production). In one embodiment, these droplets can be solidified in free fall through a solidification tower. The droplets can be collected in a container at the bottom of the solidification tower or can be pneumatically conveyed into a collection container. The outlet 3 also can be vibrated to influence the size of the droplets.

In view of the many possible embodiments to which the principles of the disclosed process, apparatus and system may be applied, it should be recognized that the illustrated embodiments are only preferred examples and should not be taken as limiting the scope of the invention.

What is claimed is:

1. A method for producing solid multicrystalline silicon ingots or wafers, comprising:
introducing a silicon-bearing gas into a reactor chamber, wherein the reaction chamber includes a reactor chamber wall having (i) an inside surface facing a reaction space and (ii) an opposing outside surface, and a product outlet;
generating a plasma in the reactor space;
thermally decomposing the silicon-bearing gas by subjecting the silicon-bearing gas to a sufficient temperature to produce liquid silicon;
maintaining the inside surface of the reactor chamber wall at an equilibrium temperature below the melting point temperature of silicon while thermally decomposing the silicon-bearing gas; and
introducing the liquid silicon from the product outlet directly into a module for casting the liquid silicon into solid multicrystalline silicon ingots or solid multicrystalline silicon wafers.

2. The method of claim 1, wherein the steps of introducing the silicon-bearing gas into the reactor chamber through introducing the liquid silicon into the casting module all occur within a hermetically sealed environment.

3. The method of claim 1, wherein the casting module comprises continuously casting the liquid silicon into silicon ingots.

4. The method of claim 1, wherein the casting module comprises continuously depositing the liquid silicon onto a moving support substrate.

5. The method of claim 1, wherein the silicon-bearing gas is selected from SiₙH₂ₙ₊₂, wherein n is 1 to 4, dichlorosilane, trichlorosilane, silicon tetrachloride, dibromosilane, tribromosilane, silicon tetrabromide, diiodosilane, triiodosilane, silicon tetraiodide or a mixture thereof.

6. The method of claim 1, wherein the silicon-bearing gas is silane.

7. The method of claim 1, further comprising forming a solid silicon skull layer on the inside surface of the reactor chamber wall.

8. The method of claim 7, wherein the liquid silicon flows as a film along an inside surface of the solid silicon skull layer.

9. The method of claim 7, wherein the solid skull layer has a thickness of less than 200 mm.

10. The method of claim 1, wherein the inside surface wall temperature is maintained at 1 to 300° C. below the melting point temperature of silicon.

11. The method of claim 1, wherein the inside surface wall temperature is maintained at 1 to 200° C. below the melting point temperature of silicon.

12. The method of claim 1, wherein the casting module comprises an electromagnetic crucible.

13. The method of claim 1, wherein the casting module comprises a continuous casting crucible.

14. The method of claim 1, wherein the casting module comprises a foil casting system.

15. The method of claim 1, wherein the casting module comprises a wafer casting system.

16. A method for producing solid multicrystalline silicon, comprising:
introducing a silicon-bearing gas into a reactor chamber, wherein the reaction chamber includes a reactor chamber wall having (i) an inside surface facing a reaction space and (ii) an opposing outside surface, and a product outlet;
generating a plasma in the reactor space;
thermally decomposing the silicon-bearing gas in the reactor space by subjecting the silicon-bearing gas to the plasma to produce liquid silicon;
maintaining the inside surface of the reactor chamber wall at an equilibrium temperature below the melting point temperature of silicon while thermally decomposing the silicon-bearing gas; and
directly casting liquid silicon from the product outlet into solid multicrystalline silicon.

17. A solid multicrystalline silicon production system, comprising:
a silicon-bearing gas feed inlet;
a reaction chamber that includes a reactor chamber wall that defines a chamber reaction space and includes (i) an inside surface facing the reaction space and (ii) an opposing outside surface;
a plasma energy source coupled to the reaction chamber and configured to generate thermal energy within the chamber reaction space;
a product outlet configured for withdrawing liquid silicon from the reaction chamber; and
a solidification module in fluid communication with the product outlet and configured to produce solid multicrystalline silicon directly from the liquid silicon.

18. The system of claim 17, wherein the solidification module comprises means for continuously casting the liquid silicon into silicon ingots.

19. The system of claim 17, wherein the solidification module comprises means for continuously casting silicon wafers.

20. The system of claim 17, further comprising a hermetically sealed containment chamber encompassing at least the reactor chamber, the product outlet and the solidification module.

21. The system of claim 17 wherein the solidification module comprises an electromagnetic crucible.

22. The system of claim 17, wherein the solidification module comprises a continuous casting crucible.

23. The system of claim 17, wherein the solidification module comprises a foil casting system.

24. The system of claim 17, wherein the solidification module comprises a wafer casting system.
